(19) United States
(12) Patent Application Publication
(10) Pub. No.: US 2021/0036820 A1
(43) Pub. Date: Feb. 4, 2021

(54) TEST CHAMBER PARASITIC CHANNEL EQUALIZATION

(71) Applicant: QUALCOMM Incorporated, San Diego, CA (US)

(72) Inventors: Mueez AHMAD, San Diego, CA (US); Srivatsan RAJAGOPALAN, San Diego, CA (US); Igor GUTMAN, Ramat Gan (IL); Shay LANDIS, Hod Hasharon (IL)

(21) Appl. No.: 16/811,870

(22) Filed: Mar. 6, 2020

Related U.S. Application Data
(60) Provisional application No. 62/881,575, filed on Aug. 1, 2019.

(51) Int. Cl. H04L 5/00; H04L 1/06; H04B 17/00; H04B 7/0413; H04B 17/21

(52) U.S. Cl. CPC H04L 5/0048; H04L 1/0681; H04B 17/21; H04B 7/0413; H04B 17/0085

(57) ABSTRACT

Various aspects of the present disclosure generally relate to wireless communication. In some aspects, a receiver device may receive, from a tested device, a set of sounding reference signals for a testing procedure of a test chamber; determine a set of parameters of a parasitic channel of the test chamber based at least in part on a response of a set of subcarriers of the set of sounding reference signals; determine a transmission equalization matrix based at least in part on the parameters of the parasitic channel; and equalize one or more subsequent transmissions using the transmission equalization matrix. Numerous other aspects are provided.

### CROSS-REFERENCE TO RELATED APPLICATION

This Patent Application claims priority to U.S. Provisional Patent Application No. 62/881,575, filed on Aug. 1, 2019, entitled “TEST CHAMBER PARASITIC CHANNEL EQUALIZATION,” and assigned to the assignee hereof. The disclosure of the prior Application is considered part of and is incorporated by reference in this Patent Application.

### FIELD OF THE DISCLOSURE

Aspects of the present disclosure generally relate to wireless communication and to techniques and apparatuses for test chamber parasitic channel equalization.

### BACKGROUND

Wireless communication systems are widely deployed to provide various telecommunication services such as telephony, video, data, messaging, and broadcasts. Typical wireless communication systems may employ multiple-access technologies capable of supporting communication with multiple users by sharing available system resources (e.g., bandwidth, transmit power, and/or the like). Examples of such multiple-access technologies include code division multiple access (CDMA) systems, time division multiple access (TDMA) systems, frequency-division multiple access (FDMA) systems, orthogonal frequency-division multiple access (OFDMA) systems, single-carrier frequency-division multiple access (SC-FDMA) systems, time division synchronous code division multiple access (TD-SCDMA) systems, and Long Term Evolution (LTE). LTE/LTE-Advanced is a set of enhancements to the Universal Mobile Telecommunications System (UMTS) mobile standard promulgated by the Third Generation Partnership Project (3GPP).

A wireless communication network may include a number of base stations (BSs) that can support communication for a number of user equipment (UEs). A user equipment (UE) may communicate with a base station (BS) via the downlink and uplink. The downlink (or forward link) refers to the communication link from the BS to the UE, and the uplink (or reverse link) refers to the communication link from the UE to the BS. As will be described in more detail herein, a BS may be referred to as a Node B, a gNB, an access point (AP), a radio head, a transmit receive point (TRP), a New Radio (NR) BS, a 5G Node B, and/or the like.

The above multiple access technologies have been adopted in various telecommunication standards to provide a common protocol that enables different user equipment to communicate on a municipal, national, regional, and even global level. New Radio (NR), which may also be referred to as 5G, is a set of enhancements to the LTE mobile standard promulgated by the Third Generation Partnership Project (3GPP). NR is designed to better support mobile broadband Internet access by improving spectral efficiency, lowering costs, improving services, making use of new spectrum, and better integrating with other open standards using orthogonal frequency division multiplexing (OFDM) with a cyclic prefix (CP) (CP-OFDM) on the downlink (DL), using CP-OFDM and/or SC-FDM (e.g., also known as discrete Fourier transform spread OFDM (DFT-s-OFDM)) on the uplink (UL), as well as supporting beamforming, multiple-input multiple-output (MIMO) antenna technology, and carrier aggregation. However, as the demand for mobile broadband access continues to increase, there exists a need for further improvements in LTE and NR technologies. Preferably, these improvements should be applicable to other multiple access technologies and the telecommunication standards that employ these technologies.

### SUMMARY

In some aspects, a method for calibration performed by a receiver device may include receiving, from a tested device, a set of sounding reference signals for a testing procedure of a test chamber; determining a set of parameters of a parasitic channel of the test chamber based at least in part on a response of a set of subcarriers of the set of sounding reference signals; determining a transmission equalization matrix based at least in part on the set of parameters of the parasitic channel; and equalizing one or more subsequent transmissions using the transmission equalization matrix.

In some aspects, a receiver device for wireless communication may include a memory and one or more processors operatively coupled to the memory. The memory and the one or more processors may be configured to receive, from a tested device, a set of sounding reference signals for a testing procedure of a test chamber; determine a set of parameters of a parasitic channel of the test chamber based at least in part on a response of a set of subcarriers of the set of sounding reference signals; determine a transmission equalization matrix based at least in part on the set of parameters of the parasitic channel; and equalize one or more subsequent transmissions using the transmission equalization matrix.

In some aspects, a non-transitory computer-readable medium may store one or more instructions for wireless communication. The one or more instructions, when executed by one or more processors of a receiver device, may cause the one or more processors to receive, from a tested device, a set of sounding reference signals for a testing procedure of a test chamber; determine a set of parameters of a parasitic channel of the test chamber based at least in part on a response of a set of subcarriers of the set of sounding reference signals; determine a transmission equalization matrix based at least in part on the set of parameters of the parasitic channel; and equalize one or more subsequent transmissions using the transmission equalization matrix.

In some aspects, an apparatus for wireless communication may include means for receiving, from a tested device, a set of sounding reference signals for a testing procedure of a test chamber; means for determining a set of parameters of a parasitic channel of the test chamber based at least in part on a response of a set of subcarriers of the set of sounding reference signals; means for determining a transmission equalization matrix based at least in part on the set of parameters of the parasitic channel; and means for equalizing one or more subsequent transmissions using the transmission equalization matrix.

Aspects generally include a method, apparatus, system, computer program product, non-transitory computer-readable medium, user equipment, base station, wireless communication device, and/or processing system as substantially described herein with reference to and as illustrated by the accompanying drawings and specification.

The foregoing has outlined rather broadly the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages will be better understood from the following description when considered in connection with the accompanying figures. Each of the figures is provided for the purposes of illustration and description, and not as a definition of the limits of the claims.

### BRIEF DESCRIPTION OF THE DRAWINGS

So that the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects. The same reference numbers in different drawings may identify the same or similar elements.

FIG. 1 is a block diagram conceptually illustrating an example of a wireless communication network within which user equipment (UEs) and base stations (BSs) that are tested in a test chamber may be deployed, in accordance with various aspects of the present disclosure.

FIG. 2 is a block diagram conceptually illustrating an example of a BS and a UE that may be tested, such as in a test chamber, in accordance with various aspects of the present disclosure.

FIGS. 3A and 3B are diagrams illustrating an example of test chamber parasitic channel equalization, in accordance with various aspects of the present disclosure.

FIG. 4 is a diagram illustrating an example process performed, for example, by a receiver device, in accordance with various aspects of the present disclosure.

### DETAILED DESCRIPTION

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based at least in part on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

Several aspects of telecommunication systems will now be presented with reference to various apparatuses and techniques. These apparatuses and techniques will be described in the following detailed description and illustrated in the accompanying drawings by various blocks, modules, components, circuits, steps, processes, algorithms, and/or the like (collectively referred to as “elements”). These elements may be implemented using hardware, software, or combinations thereof. Whether such elements are implemented as hardware or software depends upon the particular application and design constraints imposed on the overall system.

It should be noted that while aspects may be described herein using terminology commonly associated with 3G and/or 4G wireless technologies, aspects of the present disclosure can be applied in other generation-based communication systems, such as 5G and later, including NR technologies.

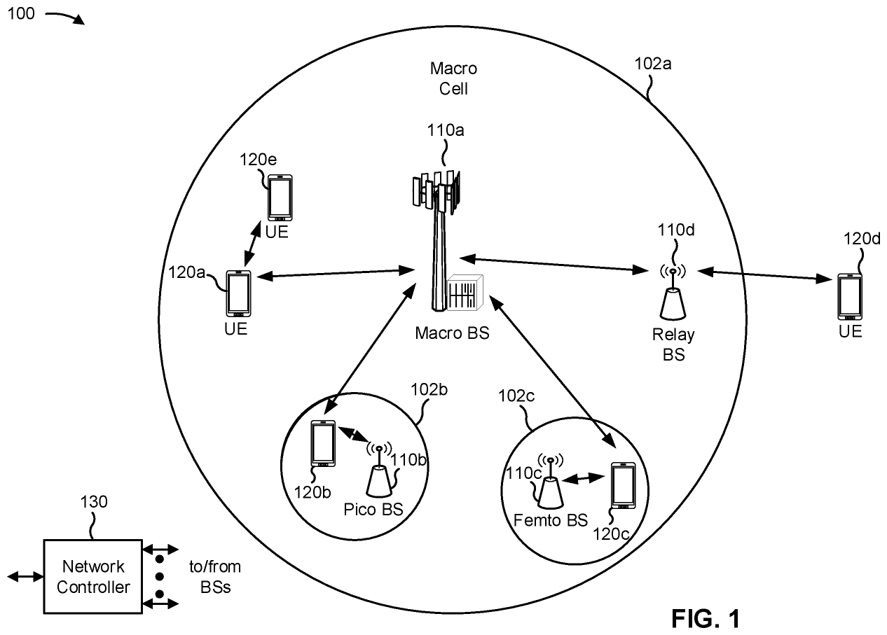

FIG. 1 is a diagram illustrating a wireless network 100 in which aspects of the present disclosure may be practiced. The wireless network 100 may be deployed in a test chamber (e.g., a BS may provide the wireless network 100 to a UE that is in a test chamber). Additionally, or alternatively, a test chamber, described herein, may be used to simulate one or more aspects of the wireless network 100. The wireless network 100 may be an LTE network or some other wireless network, such as a 5G or NR network. The wireless network 100 may include a number of BSs 110 (shown as BS 110a, BS 110b, BS 110c, and BS 110d) and other network entities. ABS is an entity that communicates with user equipment (UEs) and may also be referred to as a base station, a NR BS, a Node B, a gNB, a 5G node B (NB), an access point, a transmit receive point (TRP), and/or the like. Each BS may provide communication coverage for a particular geographic area. In 3GPP, the term “cell” can refer to a coverage area of a BS and/or a BS subsystem serving this coverage area, depending on the context in which the term is used.

A BS may provide communication coverage for a macro cell, a pico cell, a femto cell, and/or another type of cell. A macro cell may cover a relatively large geographic area (e.g., several kilometers in radius) and may allow unrestricted access by UEs with service subscription. A pico cell may cover a relatively small geographic area and may allow unrestricted access by UEs with service subscription. A femto cell may cover a relatively small geographic area (e.g., a home) and may allow restricted access by UEs having association with the femto cell (e.g., UEs in a closed subscriber group (CSG)). ABS for a macro cell may be referred to as a macro BS. ABS for a pico cell may be referred to as a pico BS. A BS for a femto cell may be referred to as a femto BS or a home BS. In the example shown in FIG. 1, a BS 110a may be a macro BS for a macro cell 102a, a BS 110b may be a pico BS for a pico cell 102b, and a BS 110c may be a femto BS for a femto cell 102c. A BS may support one or multiple (e.g., three) cells. The terms “eNB”, “base station”, “NR BS”, “gNB”, “TRP”, “AP”, “node B”, “5G NB”, and “cell” may be used interchangeably herein.

In some aspects, a cell may not necessarily be stationary, and the geographic area of the cell may move according to the location of a mobile BS. In some aspects, the BSs may be interconnected to one another and/or to one or more other BSs or network nodes (not shown) in the wireless network 100 through various types of backhaul interfaces such as a direct physical connection, a virtual network, and/or the like using any suitable transport network.

Wireless network 100 may also include relay stations. A relay station is an entity that can receive a transmission of data from an upstream station (e.g., a BS or a UE) and send a transmission of the data to a downstream station (e.g., a UE or a BS). A relay station may also be a UE that can relay transmissions for other UEs. In the example shown in FIG. 1, a relay station 110d may communicate with macro BS 110a and a UE 120d in order to facilitate communication between BS 110a and UE 120d. A relay station may also be referred to as a relay BS, a relay base station, a relay, and/or the like.

Wireless network 100 may be a heterogeneous network that includes BSs of different types, e.g., macro BSs, pico BSs, femto BSs, relay BSs, and/or the like. These different types of BSs may have different transmit power levels, different coverage areas, and different impacts on interference in wireless network 100. For example, macro BSs may have a high transmit power level (e.g., 5 to 40 Watts) whereas pico BSs, femto BSs, and relay BSs may have lower transmit power levels (e.g., 0.1 to 2 Watts).

A network controller 130 may couple to a set of BSs and may provide coordination and control for these BSs. Network controller 130 may communicate with the BSs via a backhaul. The BSs may also communicate with one another, e.g., directly or indirectly via a wireless or wireline backhaul.

UEs 120 (e.g., 120a, 120b, 120c) may be dispersed throughout wireless network 100, and each UE may be stationary or mobile. A UE may also be referred to as an access terminal, a terminal, a mobile station, a subscriber unit, a station, and/or the like. A UE may be a cellular phone (e.g., a smart phone), a personal digital assistant (PDA), a wireless modem, a wireless communication device, a handheld device, a laptop computer, a cordless phone, a wireless local loop (WLL) station, a tablet, a camera, a gaming device, a netbook, a smartbook, an ultrabook, a medical device or equipment, biometric sensors/devices, wearable devices (smart watches, smart clothing, smart glasses, smart wrist bands, smart jewelry (e.g., smart ring, smart bracelet)), an entertainment device (e.g., a music or video device, or a satellite radio), a vehicular component or sensor, smart meters/sensors, industrial manufacturing equipment, a global positioning system device, or any other suitable device that is configured to communicate via a wireless or wired medium.

Some UEs may be considered machine-type communication (MTC) or evolved or enhanced machine-type communication (eMTC) UEs. MTC and eMTC UEs include, for example, robots, drones, remote devices, sensors, meters, monitors, location tags, and/or the like, that may communicate with a base station, another device (e.g., remote device), or some other entity. A wireless node may provide, for example, connectivity for or to a network (e.g., a wide area network such as Internet or a cellular network) via a wired or wireless communication link. Some UEs may be considered Internet-of-Things (IoT) devices, and/or may be implemented as NB-IoT (narrowband internet of things) devices. Some UEs may be considered a Customer Premises Equipment (CPE). UE 120 may be included inside a housing that houses components of UE 120, such as processor components, memory components, and/or the like.

In general, any number of wireless networks may be deployed in a given geographic area. Each wireless network may support a particular RAT and may operate on one or more frequencies. A RAT may also be referred to as a radio technology, an air interface, and/or the like. A frequency may also be referred to as a carrier, a frequency channel, and/or the like. Each frequency may support a single RAT in a given geographic area in order to avoid interference between wireless networks of different RATs. In some cases, NR or 5G RAT networks may be deployed.

In some aspects, two or more UEs 120 (e.g., shown as UE 120a and UE 120e) may communicate directly using one or more sidelink channels (e.g., without using a base station 110 as an intermediary to communicate with one another). For example, the UEs 120 may communicate using peer-to-peer (P2P) communications, device-to-device (D2D) communications, a vehicle-to-everything (V2X) protocol (e.g., which may include a vehicle-to-vehicle (V2V) protocol, a vehicle-to-infrastructure (V2I) protocol, and/or the like), a mesh network, and/or the like. In this case, the UE 120 may perform scheduling operations, resource selection operations, and/or other operations described elsewhere herein as being performed by the base station 110.

As indicated above, FIG. 1 is provided as an example. Other examples may differ from what is described with regard to FIG. 1.

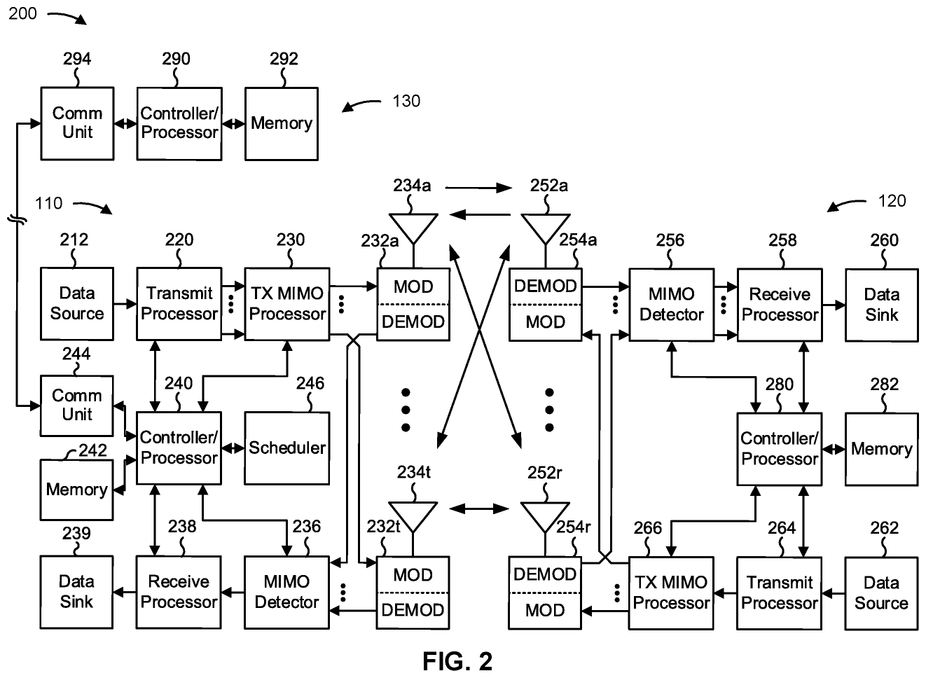

FIG. 2 shows a block diagram of a design 200 of base station 110 and UE 120, which may be one of the base stations and one of the UEs in FIG. 1, in communication, such as in a test chamber. Base station 110 may be equipped with T antennas 234a through 234t, and UE 120 may be equipped with R antennas 252a through 252r, where in general T≥1 and R≥1.

At base station 110, a transmit processor 220 may receive data from a data source 212 for one or more UEs, select one or more modulation and coding schemes (MCS) for each UE based at least in part on channel quality indicators (CQIs) received from the UE, process (e.g., encode and modulate) the data for each UE based at least in part on the MCS(s) selected for the UE, and provide data symbols for all UEs. Transmit processor 220 may also process system information (e.g., for semi-static resource partitioning information (SRPI) and/or the like) and control information (e.g., CQI requests, grants, upper layer signaling, and/or the like) and provide overhead symbols and control symbols. Transmit processor 220 may also generate reference symbols for reference signals (e.g., the cell-specific reference signal (CRS)) and synchronization signals (e.g., the primary synchronization signal (PSS) and secondary synchronization signal (SSS)). A transmit (TX) multiple-input multiple-output (MIMO) processor 230 may perform spatial processing (e.g., precoding) on the data symbols, the control symbols, the overhead symbols, and/or the reference symbols, if applicable, and may provide T output symbol streams to T modulators (MODs) 232a through 232t. Each modulator 232 may process a respective output symbol stream (e.g., for OFDM and/or the like) to obtain an output sample stream. Each modulator 232 may further process (e.g., convert to analog, amplify, filter, and upconvert) the output sample stream to obtain a downlink signal. T downlink signals from modulators 232a through 232t may be transmitted via T antennas 234a through 234t, respectively. According to various aspects described in more detail below, the synchronization signals can be generated with location encoding to convey additional information.

At UE 120, antennas 252a through 252r may receive the downlink signals from base station 110 and/or other base stations and may provide received signals to demodulators (DEMODs) 254a through 254r, respectively. Each demodulator 254 may condition (e.g., filter, amplify, downconvert, and digitize) a received signal to obtain input samples. Each demodulator 254 may further process the input samples (e.g., for OFDM and/or the like) to obtain received symbols. A MIMO detector 256 may obtain received symbols from all R demodulators 254a through 254r, perform MIMO detection on the received symbols if applicable, and provide detected symbols. A receive processor 258 may process (e.g., demodulate and decode) the detected symbols, provide decoded data for UE 120 to a data sink 260, and provide decoded control information and system information to a controller/processor 280. A channel processor may determine reference signal received power (RSRP), received signal strength indicator (RSSI), reference signal received quality (RSRQ), channel quality indicator (CQI), and/or the like. In some aspects, one or more components of UE 120 may be included in a housing.

On the uplink, at UE 120, a transmit processor 264 may receive and process data from a data source 262 and control information (e.g., for reports comprising RSRP, RSSI, RSRQ, CQI, and/or the like) from controller/processor 280. Transmit processor 264 may also generate reference symbols for one or more reference signals. The symbols from transmit processor 264 may be precoded by a TX MIMO processor 266 if applicable, further processed by modulators 254a through 254r (e.g., for DFT-s-OFDM, CP-OFDM, and/or the like), and transmitted to base station 110. At base station 110, the uplink signals from UE 120 and other UEs may be received by antennas 234, processed by demodulators 232, detected by a MIMO detector 236 if applicable, and further processed by a receive processor 238 to obtain decoded data and control information sent by UE 120. Receive processor 238 may provide the decoded data to a data sink 239 and the decoded control information to controller/processor 240. Base station 110 may include communication unit 244 and communicate to network controller 130 via communication unit 244. Network controller 130 may include communication unit 294, controller/processor 290, and memory 292.

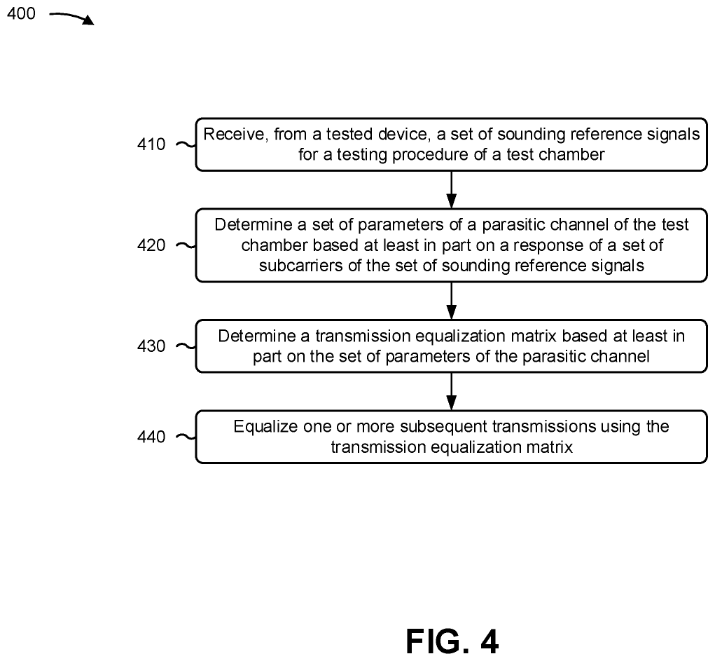

Controller/processor 240 of base station 110, controller/processor 280 of UE 120, and/or any other component(s) of FIG. 2 may perform one or more techniques associated with test chamber parasitic channel equalization, as described in more detail elsewhere herein. For example, controller/processor 240 of base station 110, controller/processor 280 of UE 120, and/or any other component(s) of FIG. 2 may perform or direct operations of, for example, process 400 of FIG. 4 and/or other processes as described herein. Memories 242 and 282 may store data and program codes for base station 110 and UE 120, respectively. In some aspects, memory 242 and/or memory 282 may comprise a non-transitory computer-readable medium storing one or more instructions for wireless communication. For example, the one or more instructions, when executed by one or more processors of the base station 110 and/or the UE 120, may perform or direct operations of, for example, process 400 of FIG. 4 and/or other processes as described herein. A scheduler 246 may schedule UEs for data transmission on the downlink and/or uplink.

In some aspects, a receiver device (e.g., base station 110) may include means for receiving, from a tested device, a set of sounding reference signals for a testing procedure of a test chamber; means for determining a set of parameters of a parasitic channel of the test chamber based at least in part on a response of a set of subcarriers of the set of sounding reference signals; means for determining a transmission equalization matrix based at least in part on the set of parameters of the parasitic channel; and means for equalizing one or more subsequent transmissions using the transmission equalization matrix; and/or the like. In some aspects, such means may include one or more components of base station 110 described in connection with FIG. 2, such as antenna 234, DEMOD 232, MIMO detector 236, receive processor 238, controller/processor 240, transmit processor 220, TX MIMO processor 230, MOD 232, antenna 234, and/or the like.

As indicated above, FIG. 2 is provided as an example. Other examples may differ from what is described with regard to FIG. 2.

Test chambers may be used to test devices that are to be deployed in a wireless communications network. For example, a test chamber may be used for pre-deployment testing of a millimeter wave (mmWave) UE. In this case, a testing device (e.g., a BS), which may be located outside of the test chamber or within the test chamber, may radiate signals over the air to a tested device (e.g., a UE, which may be referred to as a device under test (DUT)), which is located within the test chamber. The testing device may apply a test-defined fading channel (e.g., a baseband channel) and channel noise to generate a signal to enable testing of the tested device. However, when the signal radiates within the test chamber, the signal may experience a quasi-static over the air channel of the test chamber. The quasi-static over the air channel of the test chamber may be referred to as a parasitic channel. A transmitted signal in the test chamber may be modeled as:

Y=H_{chamber}·(H·P·X+N)

where Y represents a received signal, H_{chamber} is a matrix that represents a parasitic channel of the test chamber, H is the baseband channel of a testing device, P is a baseband precoding matrix, X is a vector of the baseband transmitted signal, and N is a channel noise vector to control a signal to noise ratio.

As a result of the parasitic channel, results of testing of the tested device may fail to correspond to a set of reference results (e.g., simulation data, standard defined reference thresholds, and/or the like). In other words, when attempting to determine whether the tested device is operating as intended, the parasitic channel may cause measured performance of the tested device to deviate from a reference performance even when the tested device is operating as desired. Alternatively, the parasitic channel may cause a tested device that is not operating as intended to appear to conform with the reference performance.

In some testing procedures, the reference performance may be modified to account for the parasitic channel. However, the parasitic channel may be determined at least in part by an orientation of the tested device within the test chamber (e.g., an angle of the tested device relative to a transmit antenna of the testing device), a geometry of the test chamber, a geometry or orientation of another component within the test chamber, and/or the like. Thus, incorporating the parasitic channel into reference performance values may require exact measurements of an orientation of a reference tested device and exact alignment of an actual tested device with the orientation of the reference tested device. Thus, incorporating the parasitic channel into the reference performance values may result in excessive difficulty in accurate testing using a test chamber.

Some aspects described herein enable test chamber parasitic channel equalization. For example, a transmitter device (e.g., a UE that is a tested device) may transmit a set of sounding reference signals to a receiver device (e.g., a BS that is a testing device) to enable the receiver device to calibrate for the parasitic channel. In this case, the receiver device may estimate the parasitic channel using a zero-forcing technique on each sub-carrier associated with the set of sounding reference signals, and may determine a transmission equalization factor to apply to subsequent transmissions. Based at least in part on applying the transmission equalization factor to the subsequent transmissions, the parasitic channel may be equalized (e.g., canceled out), thereby enabling measurements of performance of the tested device without the parasitic channel altering the measurements. In this way, an accuracy of testing procedures using a testing chamber may be improved, and a difficulty in performing testing procedures using a testing chamber may be reduced.

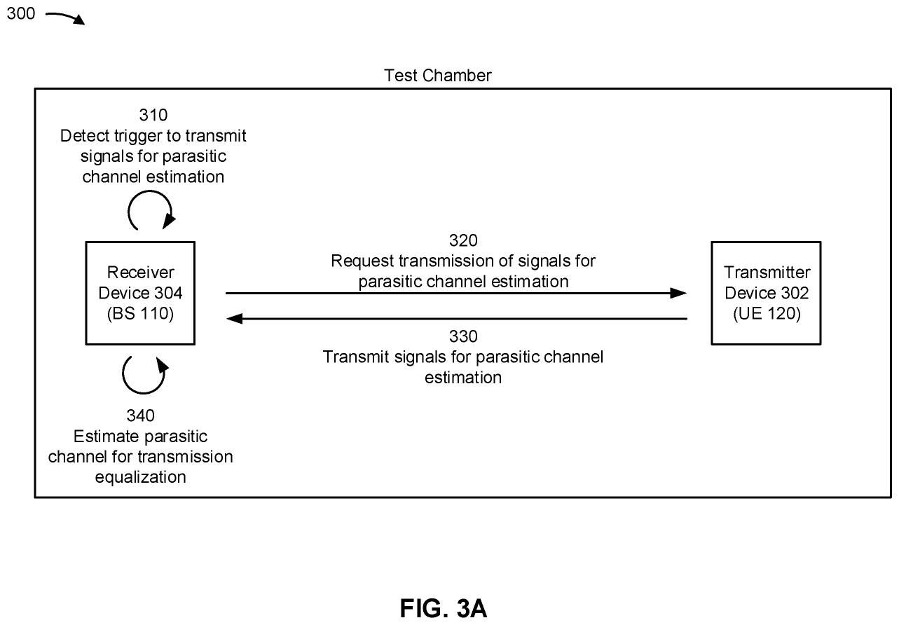

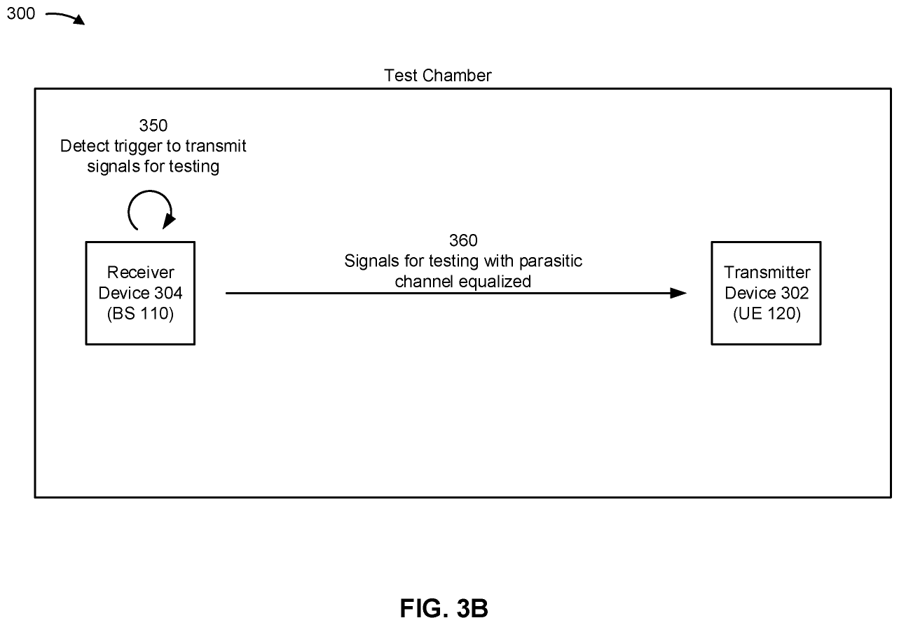

FIGS. 3A and 3B are diagrams illustrating an example 300 of test chamber parasitic channel equalization, in accordance with various aspects of the present disclosure. As shown in FIGS. 3A and 3B, example 300 may include a transmitter device 302 (e.g., a UE 120 that may be a tested device) and a receiver device 304 (e.g., a BS 110 that may be a testing device). In some aspects, transmitter device 302 and/or receiver device 304 may be located within a test chamber.

As further shown in FIG. 3A, and by reference number 310, receiver device 304 may detect a trigger to perform parasitic channel estimation. For example, receiver device 304 may determine that an initial calibration procedure is to be performed for a test chamber. In some aspects, receiver device 304 may determine that an orientation of transmitter device 302 or another component within the test chamber has been changed and the test chamber is to be recalibrated. For example, when an angle of transmitter device 302 is altered with respect to an antenna of receiver device 304, the parasitic channel may change and receiver device 304 may request that transmitter device 302 transmit a set of reference signals to enable a new parasitic channel estimation procedure to be performed. Additionally, or alternatively, receiver device 304 may determine to trigger a calibration procedure for parasitic channel estimation periodically. For example, receiver device 304 may determine that a threshold period of time has elapsed from a previous determination of the parasitic channel, and may determine to perform a new determination of the parasitic channel to account for changes to the parasitic channel (e.g., as a result of vibrations altering an orientation of transmitter device 302, or other changes).

As further shown in FIG. 3A, and by reference number 320, receiver device 304 may transmit a request for transmission of reference signals for parasitic channel estimation. For example, receiver device 304 may request that transmitter device 302 transmit a set of reference signals to enable a calibration procedure to be performed on the test chamber and to enable parasitic channel equalization to be performed based at least in part on results of the calibration procedure. In this case, receiver device 304 may provide an instruction indicating a type of reference signals to transmit, a port configuration for the set of reference signals, and/or the like, as described in more detail herein.

As further shown in FIG. 3A, and by reference number 330, transmitter device 302 may transmit the set of reference signals and receiver device 304 may receive the set of reference signals. For example, transmitter device 302 may transmit and receiver device 304 may receive a set of sounding reference signals. In some aspects, transmitter device 302 may transmit the set of reference signals using a two-port sounding reference signal configuration. For example, transmitter device 302 may transmit and receiver device 304 may receive a plurality of two-port sounding reference signals using a plurality of ports, concurrently. In some aspects, transmitter device 302 may transmit a set of one-port sounding reference signals, sequentially. For example, transmitter device 302 may transmit a first one-port sounding reference signal using a first port, then switch to transmitting a second one-port sounding reference signal using a second port.

As further shown in FIG. 3A, and by reference number 340, receiver device 304 may estimate a parasitic channel and may determine a transmission equalization matrix or a set of transmission equalization matrices based at least in part on the set of reference signals. For example, receiver device 304 may determine an effect of the parasitic channel on the set of sounding reference signals, and may determine the transmission equalization factor in order to enable equalization of subsequent transmissions. In some aspects, receiver device 304 may determine a response (e.g., a zero-forcing response or another type of response) for each sub-carrier of a channel on which the set of reference signals is transmitted. For example, receiver device 304 may determine:

H_{chamber}⁺=(H_{chamber}^{H}·H_{chamber})⁻¹·H_{chamber}^{H}

where H_{chamber}⁺ represents a transmission equalization factor, H_{chamber}⁺ represents the zero-forcing response of each subcarrier, and H_{chamber} is a matrix that represents the parasitic channel added by the test chamber.

As shown in FIG. 3B, and by reference numbers 350 and 360, at a subsequent time, receiver device 304 may detect a trigger to transmit signals for testing and may use the equalization factor to equalize the signals. For example, receiver device 304 may transmit one or more equalized signals to enable testing of transmitter device 302. In this case, applying the transmission equalization factor results in a signal being equalized such that:

Y=H_{chamber}⁺·H_{chamber}·(H·P·X+N)

H_{chamber}⁺·H_{chamber}=I

Y=H·P·X+N

where I represents an identity matrix. In this way, a measurement of the signal is equalized such that the parasitic channel of the test chamber does not alter the measurement of the signal and cause measured performance of a tested device (e.g., transmitter device 302) to deviate from a reference measurement when the tested device is operating as intended.

As indicated above, FIGS. 3A and 3B are provided as an example. Other examples may differ from what is described with respect to FIGS. 3A and 3B.

FIG. 4 is a diagram illustrating an example process 400 performed, for example, by a receiver device, in accordance with various aspects of the present disclosure. Example process 400 is an example where a receiver device (e.g., receiver device 304, BS 110, and/or the like) performs operations associated with test chamber parasitic channel equalization.

As shown in FIG. 4, in some aspects, process 400 may include receiving, from a tested device, a set of sounding reference signals for a testing procedure of a test chamber (block 410). For example, the receiver device (e.g., using transmit processor 220, receive processor 238, controller/processor 240, memory 242, and/or the like) may receive, from a tested device, a set of sounding reference signals for a testing procedure of a test chamber, as described above.

As further shown in FIG. 4, in some aspects, process 400 may include determining a set of parameters of a parasitic channel of the test chamber based at least in part on a response of a set of subcarriers of the set of sounding reference signals (block 420). For example, the receiver device (e.g., using transmit processor 220, receive processor 238, controller/processor 240, memory 242, and/or the like) may determine the set of parameters of a parasitic channel of the test chamber based at least in part on a response of a set of subcarriers of the set of sounding reference signals, as described above.

As further shown in FIG. 4, in some aspects, process 400 may include determining a transmission equalization matrix based at least in part on the parameter of the parasitic channel (block 430). For example, the receiver device (e.g., using transmit processor 220, receive processor 238, controller/processor 240, memory 242, and/or the like) may determine a transmission equalization matrix based at least in part on the parameter of the parasitic channel, as described above.

As further shown in FIG. 4, in some aspects, process 400 may include equalizing one or more subsequent transmissions using the transmission equalization matrix (block 440). For example, the receiver device (e.g., using transmit processor 220, receive processor 238, controller/processor 240, memory 242, and/or the like) may equalize one or more subsequent transmissions using the transmission equalization matrix, as described above.

Process 400 may include additional aspects, such as any single aspect or any combination of aspects described below and/or in connection with one or more other processes described elsewhere herein.

In a first aspect, the set of sounding reference signals is a set of two-port sounding reference signals or one-port sounding reference signals radiated through two transmission ports.

In a second aspect, alone or in combination with the first aspect, process 400 includes providing an instruction to trigger the tested device to transmit the set of sounding reference signals.

In a third aspect, alone or in combination with one or more of the first and second aspects, process 400 includes providing the instruction periodically.

In a fourth aspect, alone or in combination with one or more of the first through third aspects, process 400 includes providing the instruction based at least in part on a change to the test chamber.

In a fifth aspect, alone or in combination with one or more of the first through fourth aspects, the change to the test chamber is a change to an orientation of the tested device in the test chamber or to an orientation of another component in the test chamber.

In a sixth aspect, alone or in combination with one or more of the first through fifth aspects, process 400 includes measuring the parasitic channel of the test chamber based at least in part on the set of sounding reference signals.

In a seventh aspect, alone or in combination with one or more of the first through sixth aspects, the set of parameters of the parasitic channel is represented by a matrix representing the response of the set of subcarriers.

Although FIG. 4 shows example blocks of process 400, in some aspects, process 400 may include additional blocks, fewer blocks, different blocks, or differently arranged blocks than those depicted in FIG. 4. Additionally, or alternatively, two or more of the blocks of process 400 may be performed in parallel.

The foregoing disclosure provides illustration and description, but is not intended to be exhaustive or to limit the aspects to the precise form disclosed. Modifications and variations may be made in light of the above disclosure or may be acquired from practice of the aspects.

As used herein, the term “component” is intended to be broadly construed as hardware, firmware, and/or a combination of hardware and software. As used herein, a processor is implemented in hardware, firmware, and/or a combination of hardware and software.

As used herein, satisfying a threshold may, depending on the context, refer to a value being greater than the threshold, greater than or equal to the threshold, less than the threshold, less than or equal to the threshold, equal to the threshold, not equal to the threshold, and/or the like.

It will be apparent that systems and/or methods described herein may be implemented in different forms of hardware, firmware, and/or a combination of hardware and software. The actual specialized control hardware or software code used to implement these systems and/or methods is not limiting of the aspects. Thus, the operation and behavior of the systems and/or methods were described herein without reference to specific software code—it being understood that software and hardware can be designed to implement the systems and/or methods based, at least in part, on the description herein.

Even though particular combinations of features are recited in the claims and/or disclosed in the specification, these combinations are not intended to limit the disclosure of various aspects. In fact, many of these features may be combined in ways not specifically recited in the claims and/or disclosed in the specification. Although each dependent claim listed below may directly depend on only one claim, the disclosure of various aspects includes each dependent claim in combination with every other claim in the claim set. A phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

No element, act, or instruction used herein should be construed as critical or essential unless explicitly described as such. Also, as used herein, the articles “a” and “an” are intended to include one or more items, and may be used interchangeably with “one or more.” Furthermore, as used herein, the terms “set” and “group” are intended to include one or more items (e.g., related items, unrelated items, a combination of related and unrelated items, and/or the like), and may be used interchangeably with “one or more.” Where only one item is intended, the phrase “only one” or similar language is used. Also, as used herein, the terms “has,” “have,” “having,” and/or the like are intended to be open-ended terms. Further, the phrase “based on” is intended to mean “based, at least in part, on” unless explicitly stated otherwise.

What is claimed is:

1. A method of calibration performed by a receiver device, comprising:
receiving, from a tested device, a set of sounding reference signals for a testing procedure of a test chamber;
determining a set of parameters of a parasitic channel of the test chamber based at least in part on a response of a set of subcarriers of the set of sounding reference signals;
determining a transmission equalization matrix based at least in part on the set of parameters of the parasitic channel; and
equalizing one or more subsequent transmissions using the transmission equalization matrix.

2. The method of claim 1, wherein the set of sounding reference signals is a set of two-port sounding reference signals or one-port sounding reference signals radiated through two transmission ports.

3. The method of claim 1, further comprising:
providing an instruction to trigger the tested device to transmit the set of sounding reference signals.

4. The method of claim 3, wherein providing the instruction comprises:
providing the instruction periodically.

5. The method of claim 3, wherein providing the instruction comprises:
providing the instruction based at least in part on a change to the test chamber.

6. The method of claim 5, wherein the change to the test chamber is a change to an orientation of the tested device in the test chamber or to an orientation of another component in the test chamber.

7. The method of claim 1, wherein receiving the set of sounding reference signals comprises:
measuring the parasitic channel of the test chamber based at least in part on the set of sounding reference signals.

8. The method of claim 1, wherein the set of parameters of the parasitic channel is represented by a matrix representing the response of the set of subcarriers.

9. A receiver device for wireless communication, comprising:
a memory; and
one or more processors operatively coupled to the memory, the memory and the one or more processors configured to:
receive, from a tested device, a set of sounding reference signals for a testing procedure of a test chamber;
determine a set of parameters of a parasitic channel of the test chamber based at least in part on a response of a set of subcarriers of the set of sounding reference signals;
determine a transmission equalization matrix based at least in part on the set of parameters of the parasitic channel; and
equalize one or more subsequent transmissions using the transmission equalization matrix.

10. The receiver device of claim 9, wherein the set of sounding reference signals is a set of two-port sounding reference signals or one-port sounding reference signals radiated through two transmission ports.

11. The receiver device of claim 9, wherein the one or more processors are further configured to:
provide an instruction to trigger the tested device to transmit the set of sounding reference signals.

12. The receiver device of claim 11, wherein the one or more processors, when providing the instruction, are to:
provide the instruction periodically.

13. The receiver device of claim 11, wherein the one or more processors, when providing the instruction, are to:
provide the instruction based at least in part on a change to the test chamber.

14. The receiver device of claim 13, wherein the change to the test chamber is a change to an orientation of the tested device in the test chamber or to an orientation of another component in the test chamber.

15. The receiver device of claim 9, wherein the one or more processors, when receiving the set of sounding reference signals, are to:
measure the parasitic channel of the test chamber based at least in part on the set of sounding reference signals.

16. The receiver device of claim 9, wherein the set of parameters of the parasitic channel is represented by a matrix representing the response of the set of subcarriers.

17. A non-transitory computer-readable medium storing one or more instructions for wireless communication, the one or more instructions comprising:
one or more instructions that, when executed by one or more processors of a receiver device, cause the one or more processors to:
receive, from a tested device, a set of sounding reference signals for a testing procedure of a test chamber;
determine a set of parameters of a parasitic channel of the test chamber based at least in part on a response of a set of subcarriers of the set of sounding reference signals;
determine a transmission equalization matrix based at least in part on the set of parameters of the parasitic channel; and
equalize one or more subsequent transmissions using the transmission equalization matrix .

18. The non-transitory computer-readable medium of claim 17, wherein the set of sounding reference signals is a set of two-port sounding reference signals or one-port sounding reference signals radiated through two transmission ports.

19. The non-transitory computer-readable medium of claim 17, wherein the one or more instructions, when executed by the one or more processors, further cause the one or more processors to:
provide an instruction to trigger the tested device to transmit the set of sounding reference signals.

20. The non-transitory computer-readable medium of claim 19, wherein the one or more instructions, that cause the one or more processors to provide the instruction, cause the one or more processors to:
provide the instruction periodically.

21. The non-transitory computer-readable medium of claim 19, wherein the one or more instructions, that cause the one or more processors to provide the instruction, cause the one or more processors to:
provide the instruction based at least in part on a change to the test chamber.

22. The non-transitory computer-readable medium of claim 21, wherein the change to the test chamber is a change to an orientation of the tested device in the test chamber or to an orientation of another component in the test chamber.

23. The non-transitory computer-readable medium of claim 17, wherein the one or more instructions, that cause the one or more processors to receive the set of sounding reference signals, cause the one or more processors to:
measure the parasitic channel of the test chamber based at least in part on the set of sounding reference signals.

24. The non-transitory computer-readable medium of claim 17, wherein the set of parameters of the parasitic channel is represented by a matrix representing the response of the set of subcarriers.

25. An apparatus for wireless communication, comprising:
means for receiving, from a tested device, a set of sounding reference signals for a testing procedure of a test chamber;
means for determining a set of parameters of a parasitic channel of the test chamber based at least in part on a response of a set of subcarriers of the set of sounding reference signals;
means for determining a transmission equalization matrix based at least in part on the set of parameters of the parasitic channel; and
means for equalizing one or more subsequent transmissions using the transmission equalization matrix.

26. The apparatus of claim 25, wherein the set of sounding reference signals is a set of two-port sounding reference signals or one-port sounding reference signals radiated through two transmission ports.

27. The apparatus of claim 25, further comprising:
means for providing an instruction to trigger the tested device to transmit the set of sounding reference signals.

28. The apparatus of claim 27, wherein the means for providing the instruction comprises:
means for providing the instruction periodically.

29. The apparatus of claim 27, wherein the means for providing the instruction comprises:
means for providing the instruction based at least in part on a change to the test chamber.

30. The apparatus of claim 29, wherein the change to the test chamber is a change to an orientation of the tested device in the test chamber or to an orientation of another component in the test chamber.
